(19) United States
(12) Patent Application Publication
(10) Pub. No.: US 2018/0119277 A1
(43) Pub. Date: May 3, 2018

(54) Gas Distribution Apparatus for Deposition System

(71) Applicant: HERMES-EPITEK CORPORATION, Taipei City (TW)

(72) Inventors: Junji Komeno, Kanagawa (JP); Noboru Suda, Tokyo-to (JP); Takahiro Oishi, Kanagawa (JP); Tsan-Hua Huang, Tainan City (TW); Shih-Yung Shieh, Xinzhu City (TW)

(21) Appl. No.: 15/382,089

(22) Filed: Dec. 16, 2016

(30) Foreign Application Priority Data
Nov. 1, 2016 (TW) 105135390

(51) Int. Cl. C23C 16/458; C23C 16/18

(52) U.S. Cl. CPC C23C 16/458; C23C 16/18

(57) ABSTRACT

The invention provides a gas distribution apparatus or injector in a reaction chamber comprising multiple diffusion plates arranged substantially parallel and at least one bump with slopes and substantially flat top/bottom surface to introduce at least two different reaction gases horizontally and separately into the reaction chamber while preventing condensation of adduct formed due to mixture of the reaction gases at a low temperature by avoiding back diffusion. Meanwhile any turbulence or vortex of the reaction gases is not caused because slope shape is formed at the bump.

### CROSS-REFERENCE TO RELATED APPLICATIONS

The entire contents of Taiwan Patent Application No. 105135390, filed on Nov. 1, 2016, from which this application claims priority, are expressly incorporated herein by reference.

### BACKGROUND OF THE INVENTION

### 1. Field of the Invention

The present invention generally relates to a gas distribution apparatus for a deposition system, and more particularly to a gas distribution apparatus for a deposition system which can avoid back diffusion of reaction gas and prevent reaction gases from condensation.

### 2. Description of the Related Art

Thin film deposition processes such as chemical vapor deposition (CVD) processes are carried out inside a chamber provided with a horizontal type or a rotation and revolution type reactor in semiconductor manufacturing processes. Multiple semiconductor wafers are placed on a susceptor with a heating function and the reaction gases required for the processes into the chamber and over the semiconductor wafers on the susceptor. The horizontal type or the rotation and revolution type reactor usually has a gas distribution injector for directing the reaction gases towards the susceptor in the chamber where the semiconductor wafers can be treated for processes. When the reaction gases containing materials to be deposited diffuse into the chamber through the injector, chemical reactions including undesired condensations occurs on the low temperature wall such as the gas supply pipe or the injector surface if the material sources of III groups and V groups meet together there. Ideally, the reaction gases are directed at the susceptor such that the reaction gases react as close to the wafer. However, due to imperfect temperature distribution in the chamber and uncontrolled gas flow diffusion, undesired condensation on the various walls inside chamber will occur.

FIG. 1 shows a cross sectional schematic diagram illustrating serious condensation of reaction gases in a conventional horizontal type or a rotation and revolution type of chemical vapor deposition system. Precursor gases including trimethylgallium (TMGa or Ga(CH₃)₃) as a III group material and ammonia (NH₃) as a V group material with hydrogen (H₂) and nitrogen (N₂) carrier gas are fed via individual pipe lines into the reactor to proceed chemical reaction. However, ammonia in the reactor may diffuse into the pipe lines which transport trimethylgallium. Ammonia and trimethylgallium may mix in the pipe lines to form substances with low vapor pressure and cause serious condensation.

In the paper issued by A. Thon and T. F. Kuech at Applied Physics Letters 69(1), 1 Jul. 1996, the mixture of ammonia and trimethylgallium will form an adduct (CH₃)₃ Ga:NH₃ with low vapor pressure. This process can be described by the reaction

(CH₃)₃Ga+NH₃⇔(CH₃)₃Ga:NH₃

This adduct has a moderate melting point of 31° C. and has a low vapor pressure of about 1 Torr at room temperature. Studies show that at ˜90° C. this adduct reacts to form a six member ring, Cyclo (trimmido-hexamethyltrigallium) [(CH₃)₂ Ga:NH₂]₃, with the release of one methane molecule per Ga atom. This process can be described by the reaction

3[(CH₃)₃Ga:NH₃] [symbol] [(CH₃)₂Ga:NH₂]₃+3CH₄

Thus if ammonia and trimethylgallium mix in the pipe lines, the adduct will be formed to cause serious condensation on inner sidewall.

In Japan published patent application No. 2008177380, a heating means is provided along the gas introducing pipe in the vapor phase growth system to prevent the adsorption of an adsorptivity substance to a tube wall, even when a multi pipe is used for a gas introducing pipe. However, the heating means will definitely result in a high cost and the heating means cannot be extended up to the injector.

In PCT patent application No. WO2005080631A1, an annular pressure barrier of a porous, gas-permeable material or orifice and mesh-like material is introduced to prevent undesired adducts from being formed. However, using orifice and mesh-like material to prevent undesired adducts from being formed would cause vortex before reaction gases passing through the orifice and mesh-like material. Vortex in the reaction gas flow will decrease reaction gas switching speed and the quality of film interfaces.

Therefore, there is a need for an improved deposition equipment and process that can provide uniform thin film deposition while back diffusion of reaction gas can be avoided and condensation of reaction gases can be prevented.

### SUMMARY OF THE INVENTION

One embodiment of the invention provides a deposition system, the deposition system comprises a chamber with a ceiling enclosing a processing volume, a susceptor in the chamber comprising a plurality of flat bottom surfaces for holding substrates to be deposited thin films thereon, and an injector being configured between the ceiling and the susceptor. The injector comprises at least two diffusion plates arranged substantially parallel and at least one bump with slopes and substantially flat top or bottom surfaces being configured to be located on the ceiling, the diffusion plate or the susceptor, wherein the injector introduces at least two different reaction gases flowed through the top or bottom surfaces, the slopes, and the ceiling, the diffusion plates and the susceptor.

In another embodiment, the deposition system comprises a chamber with a ceiling enclosing a processing volume, a susceptor in the chamber comprising a plurality of flat bottom surfaces for holding substrates to be deposited thin films thereon, and an injector being configured between the ceiling and the susceptor. The injector comprises a first diffusion plate and a second diffusion plate arranged substantially parallel to each other, and at least two bumps comprising a first bump on the first diffusion plate with first slopes and a substantially flat first bottom or top surface, and a second bump on the second diffusion plate with second slopes and a substantially flat second top or bottom surface, wherein the first and second bumps is located between the first and second diffusion plates, wherein at least two different reaction gases are introduced and flowed through the first and second top or bottom surfaces, the first and second slopes, and the ceiling, the first and second diffusion plates and the susceptor.

In another embodiment, the deposition system comprises a chamber with a ceiling enclosing a processing volume, a susceptor in the chamber comprising a plurality of flat bottom surfaces for holding substrates to be deposited thin films thereon, and an injector being configured between the ceiling and the susceptor. The injector comprises a first diffusion plate and a second diffusion plate arranged substantially parallel to each other, a first bump with first slopes and a substantially flat first top or bottom surface on the first diffusion plate or the second diffusion plate and between the first and second diffusion plates, and a second bump with second slopes and a substantially flat second top or bottom surface on the susceptor or the ceiling, wherein at least two different reaction gases are introduced and flowed through the first and second top or bottom surfaces, the first and second slopes, and the ceiling, the first and second diffusion plates and the susceptor.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a cross sectional schematic diagram illustrating serious condensation of reaction gases in a conventional horizontal type or a rotation and revolution type of chemical vapor deposition system.

FIG. 2 shows a schematic cross sectional diagram of a reactor according to one embodiment of the invention.

FIG. 2A shows a schematic cross sectional diagram illustrating design parameters of the injector shown in FIG. 2 according to one embodiment of the invention.

FIG. 3A shows a schematic cross sectional diagram of an injector in the reactor according to another embodiment of the invention.

FIG. 3B shows a schematic cross sectional diagram of an injector in the reactor according to another embodiment of the invention.

FIG. 3C shows a schematic cross sectional diagram of an injector in the reactor according to another embodiment of the invention.

FIG. 3D shows a schematic cross sectional diagram of an injector in the reactor according to another embodiment of the invention.

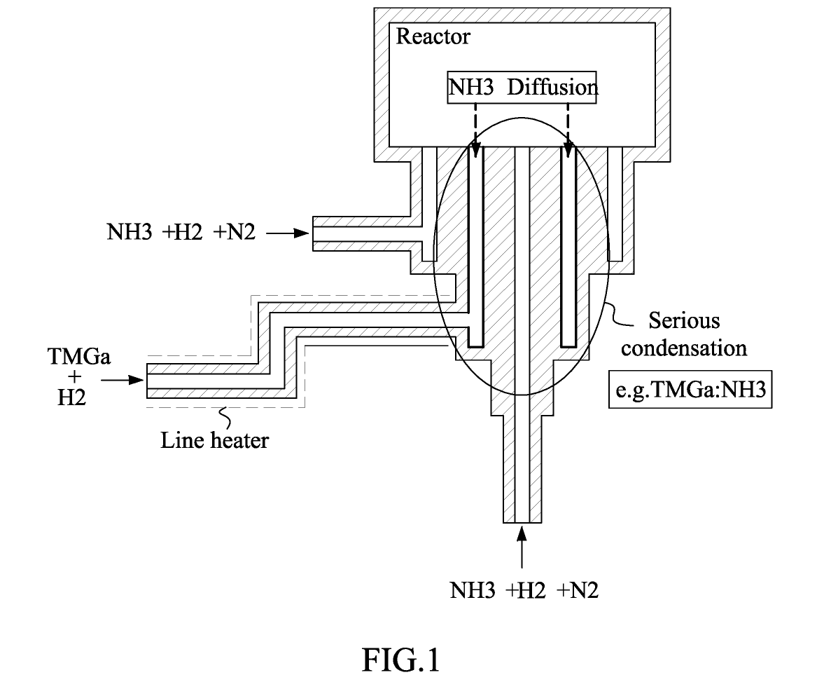

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Reference will now be made in detail to specific embodiments of the invention. Examples of these embodiments are illustrated in accompanying drawings. While the invention will be described in conjunction with these specific embodiments, it will be understood that it is not intended to limit the invention to these embodiments. On the contrary, it is intended to cover alternatives, modifications, and equivalents as may be included within the spirit and scope of the invention as defined by the appended claims. In the following description, numerous specific details are set forth in order to provide a thorough understanding of the present invention. The present invention may be practiced without some or all of these specific details. In other instances, well known process operations and elements are not described in detail in order not to unnecessarily obscure the present invention.

Embodiments of the present invention relate to a gas distribution apparatus in a chemical vapor deposition process system, particularly a metal-organic chemical vapor deposition (MOCVD) process system. The chemical vapor deposition process system further comprises a gas delivery apparatus and a reactor comprising a reaction chamber enclosing a process space and the gas distribution apparatus. The chemical vapor deposition process system is used to perform a thin film deposition process, particularly a metal-organic chemical vapor deposition process. The gas delivery apparatus introduces reaction and carrier gases from various gas sources into the reaction chamber. The gas distribution apparatus are located in the reaction chamber, while a substrate susceptor is located in the reaction chamber and beneath the process space. The substrate susceptor is utilized to sustain substrates thereon for processing. Typical substrates loaded into the deposition process system for processing includes, but are not limited to sapphire or other forms of aluminum oxide (Al₂O₃), silicon, silicon carbide (SiC), lithium aluminum oxide (LiAlO₂), lithium gallium oxide (LiGaO₂), zinc oxide (ZnO), gallium nitride (GaN), aluminum nitride (AlN), quartz, glas's, gallium arsenide (GaAs), spinel (MgAl₂O₄), derivatives thereof, or combinations thereof, etc. It is noted that the gas distribution apparatus of the invention can be applied to any suitable deposition process system. Therefore, apparatuses or components in a deposition process system other the gas distribution apparatus will not be specifically described herein. The deposition process system can further include other apparatuses or components which are well known for any one with ordinary skill in the art.

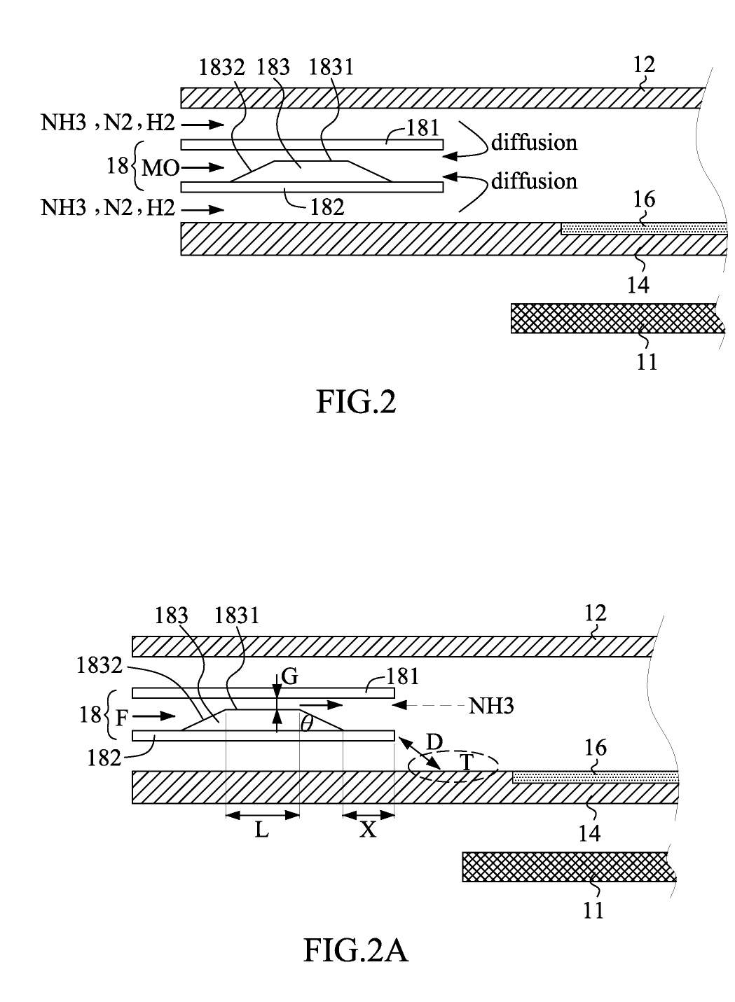

FIG. 2 shows a schematic cross sectional diagram of a reactor according to one embodiment of the invention. The reactor comprises a chamber body and a gas distribution apparatus or an injector 18 for introducing reaction and carrier gases. The gas distribution apparatus or injector 18 is configured to be installed on a ceiling 12 of the chamber body. The ceiling 12 may contain or be made of quartz, or alternatively, a metal, such as steel, stainless steel, aluminum, or alloys thereof. The quartz for the ceiling 12 is generally transparent, but alternatively, may be opaque. Portions of the chamber body other the ceiling 12 are omitted and will not be described in detail herein since the portions except the ceiling 12 are not crucial features of the claimed invention. Any design of the chamber body can be applied in the invention. A susceptor 14 is disposed within the chamber body opposite the injector 18 and the ceiling 12. The susceptor 14 has a plurality of substantially flat bottom surfaces for holding substrates 16 or wafers. The susceptor 14 may contain or be formed of solid silicon carbide. The susceptor 14 may have a core containing graphite and a silicon carbide coating. The susceptor 14 may rotate in clockwise or counterclockwise directions.

In order to heat the susceptor 14 according to temperature requirements of various film deposition processes, a heater 11 with heating elements is configured to be located under the susceptor 14. The heating elements of the heater 11 may be controlled individually and a precise temperature tuning is possible throughout the process temperature range. The heater 11 is coupled to at least one power source and a heating controller which will not be described in detail herein since the configuration and design of the heater 11 are not major features of the claimed invention.

The injector 18 comprises diffusion plates 181 and 182 and a bump 183 on the diffusion plate 182 according to one embodiment of the present invention. In this embodiment, the injector 18 is configured to horizontally inject three layers of gases. In one embodiment, a MOCVD process is performed in the deposition process system and gases including metal organic (MO) components such as trimethylgallium (TMGa or Ga(CH₃)₃) and ammonia (NH₃) or MO gas as well as hydrogen (H₂) and nitrogen (N₂) are introduced and distributed through the diffusion plates 181 and 182, and the bump 183 of the injector 18 into the chamber body. In this embodiment, MO gas is introduced and flow horizontally into the chamber body via the space between the diffusion plates 181 and the bump 183 as well as the space between the diffusion plates 181 and 182. Ammonia gases can be introduced and flow horizontally into the chamber body via the space between the ceiling 12 and the diffusion plate 181 as well as the space between the diffusion plate 182 and the susceptor 14 respectively. Nevertheless, such arrangement is not a limitation in other embodiments. Hydrogen and nitrogen gases can be introduced with MO gas and ammonia gas depending on film species grown on the substrates within this reactor.

In the embodiment shown in FIG. 2, the bump 183 is configured to be located on the diffusion plate 182. The bump 183 can be a separate component secured on the diffusion plate 182 by any suitable means or a portion of the diffusion plate 182. In this embodiment, the configuration of the bump 183 comprises a substantially flat top surface 1831 and slopes 1832. However, such configuration is not a limitation in other embodiments. The bump 183 is configured to prevent diffusion flows of other gases from other spaces and avoid vortex or turbulence of gas flow. The bump 183 is configured to decrease the space or distance between the diffusion plates 181 and 182. The narrow gap between the diffusion plates 181 and the top surface 1831 of the bump 183 is configured to increase the flow velocity of the reaction gas which is MO gas in this embodiment higher enough to avoid back-diffusion of other gases which are ammonia gases in this embodiment. The slopes 1832 are configured to avoid vortex or turbulence of gas flow which is gas flow of MO gas in this embodiment. It is noted that the numbers and configurations of the diffusion plates and bump can be choose according to requirements.

FIG. 2A shows a schematic cross sectional diagram illustrating design parameters of the injector shown in FIG. 2 according to one embodiment of the invention. The crucial design parameters of the injector 18 comprises the distance or the width of the gap G between the diffusion plate 181 and the top surface 1831, the length L of the top surface 1831, the angle θ between the slope 1832 and the diffusion plate 182, the distance X between the edge of the bump 183 or the slope 1832 and the edge of the diffusion plate 182 and the distance D between the edge of the diffusion plate 182 and the susceptor 14. The width G and the length L are configured to increase the flow velocity of the reaction gas which is MO gas in this embodiment higher enough to avoid back-diffusion of other gases which are ammonia gases in this embodiment. The angle θ is configured to avoid vortex or turbulence of gas flow of reaction gases which is MO gas in this embodiment. The distance X is configured to prevent condensation of an adduct which is (CH₃)₃ Ga:NH₃ in this embodiment. It is noted that a proper high temperature could prevent condensation of the adduct (CH₃)₃ Ga:NH₃ in this embodiment. The width G and the length L depend on the flow rate F of MO gas and the diffusion coefficient D_{NH}_{₃} of the ammonia gases in this embodiment. If the flow rate F is higher or the diffusion coefficient D_{NH}_{₃} is smaller, the length L can be shorter or the width G can be larger. If the flow rate F is lower or the diffusion coefficient D_{NH}_{₃} is larger, the length L should be longer or the width G should be smaller. The angle θ depends on Reynolds number (Re) which is a dimensionless quantity that is used to help predict similar flow patterns in different fluid flow situations. If Re of MO gas is low, the angle θ should be larger. While if Re of MO gas is larger, the angle θ should be smaller. The distance X depends on the distance D between the edge of the diffusion plate 182 and the susceptor 14 as well as the temperature T of the susceptor 14 of the region adjacent the susceptor 14. If the temperature T is higher or the distance D is smaller, the distance X should be larger. While if the temperature T is lower or the distance D is larger, the distance X can be smaller. The temperature of the injector 18 is kept high by heat transfer from the heated susceptor 14. Temperature of downstream side of the bump 183 should be high enough to prevent condensation of product of chemical reaction among reaction gases such as MO and NH₃ gases. The required temperature depends on the vapor pressure of reaction product and its supply rate. Higher temperature would raise vapor pressure of reaction gas, and condensation will become more difficult at a higher temperature. The temperature toward the downstream side of the bump 183 is high because it is closer to the heater 11. Therefore, condensation of adduct can be prevented by placing the bump 183 at an appropriate position. In one embodiment, the width G may be less than 3 mm, while the length L may be larger than 1 mm. The angle θ is acceptable if any vortex and turbulence isn't caused at the angle. The angle θ may be smaller than 30 degree.

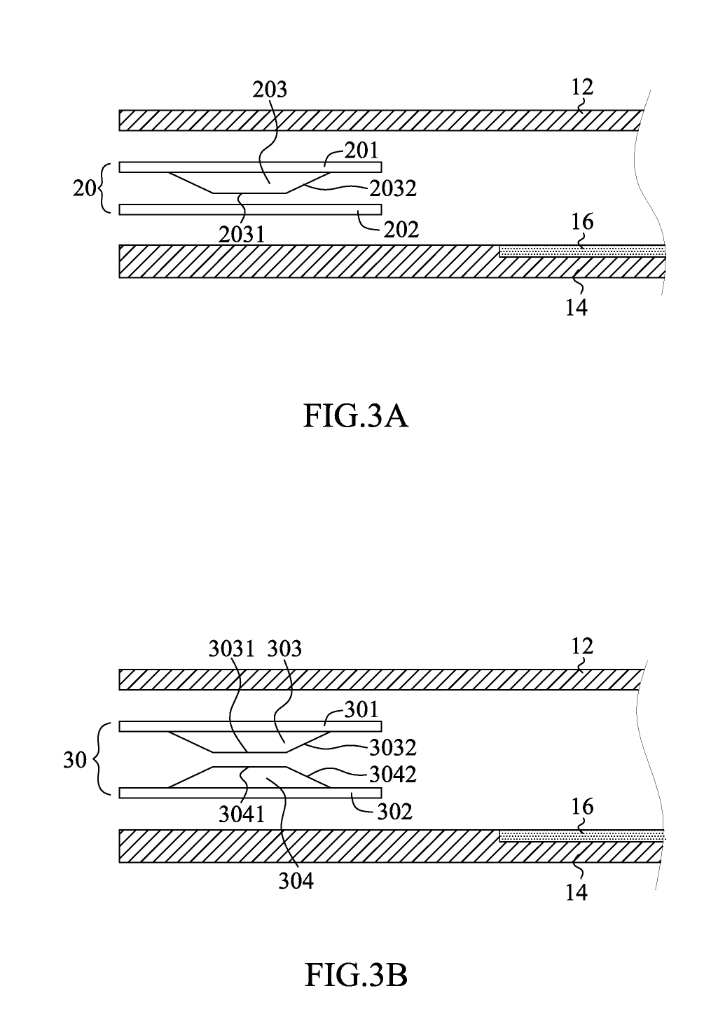

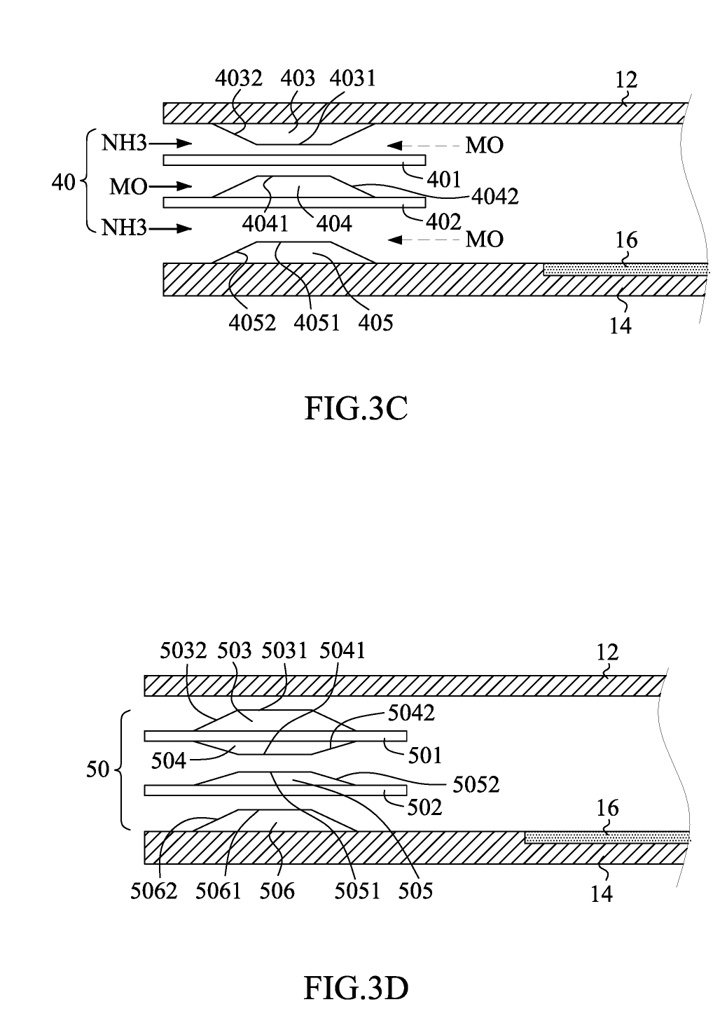

FIG. 3A shows a schematic cross sectional diagram of an injector in a reactor according to another embodiment of the invention. An injector 20 comprises diffusion plates 201 and 202 and a bump 203 on the diffusion plate 201. The injector 20 is also configured to horizontally inject three layers of gases. The bump 203 can be a separate component secured on the diffusion plate 201 by any suitable means or a portion of the diffusion plate 201. In this embodiment, the configuration of the bump 203 comprises a substantially flat bottom surface 2031 and slopes 2032. The bump 203 is configured to prevent diffusion flows of gases from adjacent spaces and avoid vortex or turbulence of gas flow. The narrow gap between the diffusion plates 202 and the bottom surface 2031 of the bump 203 is configured to increase the flow velocity of the reaction gas higher enough to avoid back-diffusion of other reaction gases from adjacent spaces between the ceiling 12 and the diffusion plate 201, and the diffusion plate 202 and the susceptor 14 respectively. The slopes 2032 are configured to avoid vortex or turbulence of gas flow. It is noted that consideration of the design parameters described set forth and shown in FIG. 2A can also be applied in a similar manner in this embodiment.

FIG. 3B shows a schematic cross sectional diagram of an injector in a reactor according to another embodiment of the invention. An injector 30 comprises a diffusion plate 301 with a bump 303 thereon and a diffusion plate 302 with a bump 304 thereon. The bumps 303 and 304 can be separate components secured on the diffusion plates 301 and 302 respectively or portions of the diffusion plates 301 and 302. The bump 303 comprises a substantially flat bottom surface 3031 and slopes 3032, while the bump 304 comprises a substantially flat top surface 3041 and slopes 3042. Similar to the embodiments shown in FIGS. 2 and 3A, the gap between the bottom surface 3031 and the top surface 3041 is configured to increase the flow velocity of the reaction gas higher enough to avoid back-diffusion of other reaction gases from adjacent spaces between the ceiling 12 and the diffusion plate 301, and the diffusion plate 302 and the susceptor 14 respectively. The slopes 3032 and 3042 are configured to avoid vortex or turbulence of gas flow. Although the bumps 303 and 304 seem be identical and arranged in a symmetric manner in this embodiment, these configurations are not limitations. The consideration of design parameters described set forth and shown in FIG. 2A can also be applied in a similar manner in this embodiment despite of a different location of the gap and the dual slopes 3032 and 3042.

FIG. 3C shows a schematic cross sectional diagram of an injector in the reactor according to another embodiment of the invention. An injector 40 comprises a diffusion plate 401, a bump 403 on the ceiling 12, a diffusion plate 402 with a bump 404 thereon and a bump 405 on the susceptor 14. The bumps 403, 404 and 405 can be separate components secured on the ceiling 12, the diffusion plates 402 and the susceptor 14 respectively, or portions of the ceiling 12, the diffusion plates 402 and the susceptor 14. The bump 403 comprises a substantially flat bottom surface 4031 and slopes 4032, while the bumps 404 and 405 comprise substantially flat top surface 4041, 4051, slopes 4042 and 4052. The consideration of design parameters described set forth and shown in FIG. 2A can also be applied in a similar manner in this embodiment. However, if reaction gases include MO gas and ammonia gases, the gap between the bump 403 and the diffusion plate 401 as well as the gap between the diffusion plate 402 and the bump 405 are configured to increase the flow velocity of ammonia gases higher enough to avoid back-diffusion of MO gas if the flow rate of MO gas is increased by the gap between the diffusion plate 401 and the bump 404. The slopes 4032, 4042 and 4052 are also configured to avoid vortex or turbulence of gas flow of reaction gases. The width of the gap between the bump 403 and the diffusion plate 401, the width of the gap between the diffusion plate 401 and the bump 404, and the width of the gap between the diffusion plate 402 and the bump 405 as well as the lengths of the surfaces 4031, 4041 and 4051 can be choose according to flow rates and diffusion coefficients of reaction gases. The angles of the slopes 4032, 4042 and 4052 also can be choose according to Reynolds number (Re) of reaction gases.

FIG. 3D shows a schematic cross sectional diagram of an injector in the reactor according to another embodiment of the invention. An injector 50 comprises a diffusion plate 501 with bumps 503 and 504, a diffusion plate 502 with a bump 505 thereon and a bump 506 on the susceptor 14. The bumps 503 and 504 comprise substantially flat top surface 5031 and bottom surface 5041 and slopes 5032 and 5042 respectively. The bumps 505 and 506 comprise substantially flat top surface 5051, 5061, slopes 5052 and 5062. Comparing to the injector 40 in FIG. 3C, the diffusion plate 502 with the bump 505 and the bump 506 on the susceptor 14 are similar to the diffusion plate 402 with the bump 404 and the bump 405 on the susceptor 14, while the diffusion plate 501 has the bumps 503 and 504 on its both surfaces. Moreover, the angles of the slopes 5032 and 5062 are larger than that of the slopes 5042 and 5052. The consideration of design parameters described set forth and shown in FIG. 2A can also be applied in a similar manner in this embodiment. Nevertheless, the width of the gap, the lengths of the surfaces and the angles of the slopes should be choose according to flow rates and diffusion coefficients of reaction gases. For example, the lengths of the top surfaces 5031 and 5036 as well as the width between the ceiling 12 and the bump 503, and the width between the diffusion plate 502 and the bump 506 can be determined according to flow rates and diffusion coefficients of reaction gases flowed through. It is noted that the lengths of the top surfaces 5031 and 5036 may be different. The width between the ceiling 12 and the bump 503, and the width between the diffusion plate 502 and the bump 506 can also be different. This is because the diffusion plate 502 and the bump 506 are closer to the heated susceptor 14 than the bump 503 and the diffusion plate 501 and the higher temperature near the susceptor can prevent condensation of adduct of the reaction gases.

The gas distribution apparatus or injector of the invention in a reaction chamber comprise multiple diffusion plates arranged substantially parallel and at least one bump with slopes and substantially flat top/bottom surface to introduce at least two different reaction gases horizontally and separately into the reaction chamber while preventing condensation of adduct formed due to mixture of the reaction gases at a low temperature by avoiding back diffusion and turbulence or vortex of the reaction gases. The bump can be arranged on the ceiling, the susceptor, or either sides of the diffusion plate. The crucial design parameters of the injector include the distance or the width of the gap G between the diffusion plate and the top/bottom surface of the bump, the length L of the top/bottom surface of the bump, the angle θ between the slope and the diffusion plate, the distance X between the edge of the bump and the edge of the diffusion plate, and the distance D between the edge of the diffusion plate and the susceptor. The width G and the length L are configured to increase the flow rate of one or more reaction gases enough high to avoid back-diffusion of the other reaction gases. The angle θ is configured to avoid vortex or turbulence of gas flow of the reaction gases. The distance X is configured to prevent condensation of adduct of the reaction gases. These design parameters can be selected according to the temperature of the susceptor, flow rates, Reynolds number (Re) and diffusion coefficients of the reaction gases. Thus the gas distribution apparatus or injector of the invention can provide uniform thin film deposition while back diffusion of reaction gas can be avoided and condensation of reaction gases can be prevented.

Although specific embodiments of the present invention have been described, it will be understood by those of skill in, the art that there are other embodiments that are equivalent to the described embodiments. Accordingly, it is to be understood that the invention is not to be limited by the specific illustrated embodiments, but only by the scope of the appended claims.

What is claimed is:

1. A deposition system, comprising:
a chamber with a ceiling enclosing a processing volume;
a susceptor in the chamber comprising a plurality of flat bottom surfaces for holding substrates to be deposited thin films thereon; and
an injector being configured between the ceiling and the susceptor, comprising,
at least two diffusion plates arranged substantially parallel; and
at least one bump with slopes and substantially flat top or bottom surfaces being configured to be located on the ceiling, the diffusion plate or the susceptor, wherein at least two different reaction gases are introduces and flow through the top or bottom surfaces, the slopes, and the ceiling, the diffusion plates and the susceptor.

2. The deposition system of claim 1, wherein the deposition system comprises a metal-organic chemical vapor deposition system, and the substrates comprise aluminum oxide, silicon, silicon carbide, lithium aluminum oxide, lithium gallium oxide, zinc oxide, gallium nitride, aluminum nitride, quartz, glass, gallium arsenide, and spinel.

3. The deposition system of claim 1 further comprising a heater with heating elements being configured to be located under the susceptor

4. The deposition system of claim 1, wherein the diffusion plates comprises a first diffusion plate and a second diffusion plate, the bump is located on the first or second diffusion plates and in a space between the first and second diffusion plates, the reaction gases comprises a first gas comprising a metal-organic component and second gases, the first gas is introduced and flows through the space between the first and second diffusion plates and the slopes and the top or bottom surfaces of the bump, while the second gases are introduced and flows through a space between the ceiling and the first diffusion plate, and a space between the second diffusion plate and the susceptor.

5. The deposition system of claim 4, wherein the metal-organic component comprises trimethylgallium, while the second gases comprise ammonia.

6. The deposition system of claim 4, wherein a width between the top or bottom surfaces of the bump and the first diffusion plate or the second diffusion plate is determined according to a flow rate and a diffusion coefficient of the first gas.

7. The deposition system of claim 4, wherein a length of the top or bottom surfaces of the bump is determined according to a flow rate and a diffusion coefficient of the first gas.

8. The deposition system of claim 4, wherein an angle between the slope and the first diffusion plate or the second diffusion plate is determined according to Reynolds number of the first gas.

9. The deposition system of claim 4, wherein a distance between the bump and an edge of the first diffusion plate or the second diffusion plate having the bump thereon is determined according to a distance between the edge and the susceptor and a temperature of the susceptor.

10. A deposition system, comprising:
a chamber with a ceiling enclosing a processing volume;
a susceptor in the chamber comprising a plurality of flat bottom surfaces for holding substrates to be deposited thin films thereon; and
an injector being configured between the ceiling and the susceptor, comprising,
a first diffusion plate and a second diffusion plate arranged substantially parallel to each other; and
at least two bumps comprising a first bump on the first diffusion plate with first slopes and a substantially flat first bottom or top surface, and a second bump on the second diffusion plate with second slopes and a substantially flat second top or bottom surface, wherein the first and second bumps is located between the first and second diffusion plates;
wherein at least two different reaction gases are introduced and flowed through the first and second top or bottom surfaces, the first and second slopes, and the ceiling, the first and second diffusion plates and the susceptor.

11. The deposition system of claim 10 further comprising a third bump on the first diffusion plate and between the ceiling and the first diffusion plate, wherein the third bump comprises third slopes and a substantially flat third top or bottom surface.

12. The deposition system of claim 10 further comprising a fourth bump on the second diffusion plate and between the susceptor and the second diffusion plate, wherein the fourth bump comprises fourth slopes and a substantially flat fourth top or bottom surface.

13. The deposition system of claim 10, wherein the reaction gases comprises a first gas comprising a metal-organic component and second gases, the first gas is introduced and flows through a space between the first and second diffusion plates and the first and second bumps, while one of the second gases is introduced and flows through a space between the ceiling, the first diffusion plate and the third bump, and the other second gas is introduced and flows a space between through the second diffusion plate, the fourth bump and the susceptor.

14. The deposition system of claim 13, wherein the metal-organic component comprises trimethylgallium comprising, while the second gases comprise ammonia.

15. The deposition system of claim 13, wherein a width between the first bottom or top surface and the second top or bottom surface is determined according to a flow rate and a diffusion coefficient of the first gas.

16. The deposition system of claim 13, wherein lengths of the first bottom or top surface and the second top or bottom surface are determined according to a flow rate and a diffusion coefficient of the first gas.

17. The deposition system of claim 13, wherein angles between the first slope and the first diffusion plate, and between the second slope and the second diffusion plate are determined according to Reynolds number of the first gas.

18. The deposition system of claim 13, wherein a distance between the first bump and an edge of the first diffusion plate is determined according to a distance between the edge of the first diffusion plate and the susceptor and a temperature of the susceptor, and a distance between the second bump and an edge of the second diffusion plate is determined according to a distance between the edge of the second diffusion plate and the susceptor and the temperature of the susceptor.

19. A deposition system, comprising:
a chamber with a ceiling enclosing a processing volume;
a susceptor in the chamber comprising a plurality of flat bottom surfaces for holding substrates to be deposited thin films thereon; and
an injector being configured between the ceiling and the susceptor, comprising,
a first diffusion plate and a second diffusion plate arranged substantially parallel to each other; and
a first bump with first slopes and a substantially flat first top or bottom surface on the first diffusion plate or the second diffusion plate and between the first and second diffusion plates; and
a second bump with second slopes and a substantially flat second top or bottom surface on the susceptor or the ceiling;
wherein at least two different reaction gases are introduced and flowed through the first and second top or bottom surfaces, the first and second slopes, and the ceiling, the first and second diffusion plates and the susceptor.

20. The deposition system of claim 19 further comprising a third bump with third slopes and a substantially flat third bottom or top surface on the ceiling or the susceptor.

21. The deposition system of claim 19, wherein the reaction gases comprises a first gas comprising a metal-organic component and second gases, the first gas is introduced and flows a space between through the first and second diffusion plates and the first bump, while one of the second gases is introduced and flows through a space between the ceiling and the first diffusion plate, and the other second gas is introduced and flows through a space between the second diffusion plate and the susceptor.

22. The deposition system of claim 21, wherein the metal-organic component comprises trimethylgallium comprising, while the second gases comprise ammonia.

23. The deposition system of claim 21, wherein a width between the first top or bottom surface and the first diffusion plate or the second diffusion plate is determined according to a flow rate and a diffusion coefficient of the first gas.

24. The deposition system of claim 21, wherein a length of the first top or bottom surface is determined according to a flow rate and a diffusion coefficient of the first gas.

25. The deposition system of claim 21, wherein an angle between the first slope and the first diffusion plate or the second diffusion plate is determined according to Reynolds number of the first gas.

26. The deposition system of claim 21, wherein a distance between the first bump and an edge of the first diffusion plate or the second diffusion plate having the first bump thereon is determined according to a distance between the edge and the susceptor and a temperature of the susceptor.
